(19) United States
(12) Patent Application Publication
(10) Pub. No.: US 2007/0166936 A1
(43) Pub. Date: Jul. 19, 2007

(54) PRE-AMORPHIZATION IMPLANTATION PROCESS AND SALICIDE PROCESS

(76) Inventors: Po-Chao Tsao, Taipei County (TW); Yi-Yiing Chiang, Taipei City (TW); Chang-Chi Huang, Miaoli (TW); Hsin-Hui Hsu, Hsinchu Hsien (TW); Ming-Tsung Chen, Hsinchu County (TW); Chien-Ting Lin, Hsinchu City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/307,008

(22) Filed: Jan. 19, 2006

(51) Int. Cl. H01L 21/336

(52) U.S. Cl. 438/299

(57) ABSTRACT

A salicide process is described, wherein a substrate with an NMOS transistor and a PMOS transistor thereon is provided. A mask layer is formed over the substrate covering the PMOS transistor but exposing the NMOS transistor, and then a pre-amorphization implantation (PAI) step is conducted to the substrate using the mask layer as a mask. After the mask layer is removed, a salicide layer is formed on the NMOS transistor and the PMOS transistor.

### BACKGROUND OF THE INVENTION

1. Field of the Invention

The present invention relates to semiconductor processes. More particularly, the present invention relates to a selective pre-amorphization implantation (PAI) process and a self-aligned silicide (salicide) process that includes the PAI process.

1. Description of the Related Art

Salicide process is important to IC fabrication for lowering the resistance of doped portions formed on a substrate. As the semiconductor technology advanced into 65 nm generation and beyond, the conventional salicide material, titanium silicide (TiSi₂), is no longer suitable for its high resistance due to linewidth reduction. Instead, Ni-salicide process becomes a promising technique in advanced processes. A nickel salicide process causes limited bridging between the metal silicide layer on a gate and that on the associated S/D regions, consumes less silicon atoms than TiSi₂ or CoSi₂ does, and exhibits almost no linewidth dependence on sheet resistance. Nickel silicide further exhibits lower film stress, i.e., causes less wafer distortion, than TiSi₂ or CoSi₂.

However, in a Ni-salicide process, NiSi-piping easily occurs to significantly lower the yield. The NiSi-piping problem is found in NMOS transistors only, which appears as lateral growth of NiSi grains to the innerside junctions of S/D and causes serious leakage. One method to solve the problem is to conduct non-selective pre-amorphization implantation (PAI) before the salicide process to pre-amorphize the silicon material of the S/D and thereby inhibit growth of NiSi grains in the later salicide process.

Nevertheless, the non-selective PAI method of the prior art adversely induces higher junction leakage and higher bipolar current of MOS transistors to increase the drain-to-drain quiescent current (I_{DDQ}) or standby current (I_{standby}) of the product. The PAI step also causes degradation of certain devices, especially most of the PMOS transistors.

### SUMMARY OF THE INVENTION

In view of the foregoing, this invention provides a selective PAI process that is capable of preventing the junction leakage or bipolar current from being increased and preventing device degradation of PMOS transistors.

This invention also provides a self-aligned silicide (salicide) process that utilizes the PAI process of this invention to eliminate the piping problem without increasing junction leakage or bipolar current or causing PMOS degradation.

In the PAI process of this invention, a mask layer is formed covering a PMOS transistor but exposing an NMOS transistor, and then amorphization implantation is conducted using the mask layer as a mask to amorphize the doped regions of the NMOS transistor.

The self-aligned silicide (salicide) process of this invention is described as follows. A substrate with an NMOS transistor and a PMOS transistor thereon is provided. A mask layer is formed over the substrate covering the PMOS transistor but exposing the NMOS transistor, and then a pre-amorphization implantation (PAI) step is performed to the substrate using the mask layer as a mask. After the mask layer is removed, a salicide layer is formed on the NMOS transistor and the PMOS transistor.

Since the PMOS transistor is masked in the PAI process of this invention, it does not suffer from increased junction leakage or bipolar current or from device degradation. On the other hand, the NMOS transistor is subject to PAI so that no piping problem occurs.

It is to be understood that both the foregoing general description and the following detailed description are exemplary, and are intended to provide further explanation of the invention as claimed.

### BRIEF DESCRIPTION OF THE DRAWINGS

FIGS. 1-4 illustrate a process flow of a self-aligned silicide (salicide) process according to a preferred embodiment of this invention.

### DESCRIPTION OF THE PREFERRED EMBODIMENTS

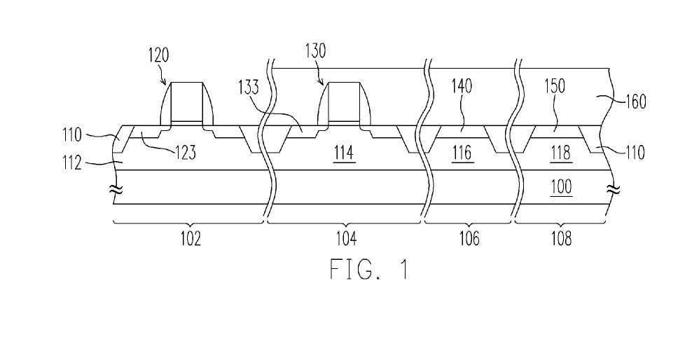

Referring to FIG. 1, a substrate 100, such as a lightly doped P-type single-crystal silicon substrate, is provided, which is formed with an NMOS transistor 102, a PMOS transistor 104, a diode 106 with its N-doped region at top, a diode 108 with its P-doped region at top, and isolation structures 110 thereon.

The NMOS transistor 102 includes a P-well 112, a gate structure 120 and an S/D region 123, and the PMOS transistor 104 includes an N-well 114, a gate structure 130 and an S/D region 133, wherein the gate structure 120 or 130 may generally include a gate insulator, a gate electrode on the gate insulator and a spacer on the sidewall of the gate electrode. The diode 106 includes a P-well 116 and an N+-doped region 140 in the P-well 116, and the diode 108 includes an N-well 118 and a P+-doped region 150 in the N-well 118. The gate structures 120 and 130, the S/D regions 123 and 133, the N+-doped region 140 and the P+-doped region 150 are predetermined to form with a salicide layer thereon.

Thereafter, a mask layer 160 as a mask in the later PAI step is formed over the substrate 100. The mask layer 160 covers the PMOS transistor 104 and the diodes 106 and 108, but exposes the NMOS transistor 102 including the gate structure 120 and the S/D region 123. The mask layer 160 may be a patterned photoresist layer, which can be formed with an ordinary lithography process, and the thickness of the mask layer 160 is sufficient to block the PMOS transistor 104 and the diodes 106 and 108 in the later PAI step.

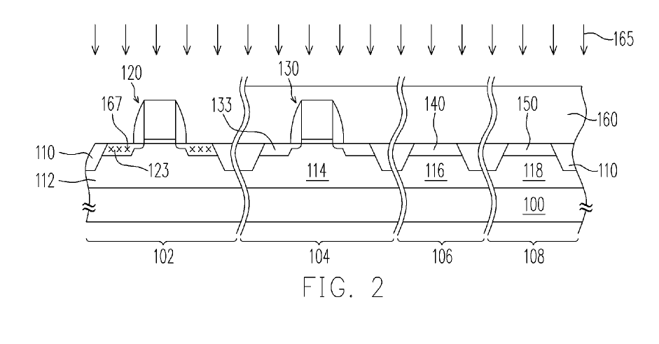

Referring to FIG. 2, pre-amorphization implantation (PAI) 165 is conducted using the mask layer 160 as a mask to implant ions 167 into the S/D region 123 of the NMOS transistor 102. To effectively amorphize the silicon material in the S/D region 123, the ion implanted is preferably a heavy ion like Si ion, germanium (Ge) ion or arsenic (As) ion. When arsenic ion is used, the implantation energy set in the PAI step 165 is preferably 15-25 keV. Since the PMOS transistor 104 and the diodes 106 and 108 are not implanted in the PAI step 165, the PMOS transistor 104 will not suffer from increased junction leakage or bipolar current or from device degradation, and the leakage of the diodes 106 and 108 will not be increased.

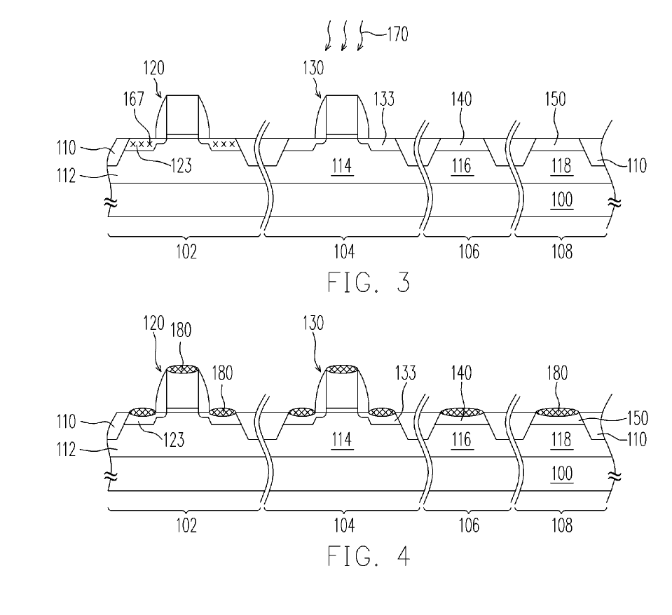

Referring to FIG. 3, the mask layer 160 is then removed. If the mask layer 160 is a patterned photoresist layer, the removal process may include an ashing step using oxygen-based plasma and a subsequent solvent stripping step. A salicide preclean step 170 is then performed, preferably with hydrogen fluoride (HF), to remove the native oxide (not shown) formed on the gate structures 120 and 130, the S/D regions 123 and 133, the N+-doped region 140 and the P+-doped region 150, so that the reaction of the silicon material therein with the later-deposited metal will not be hindered in the subsequent salicide process.

Referring to FIG. 4, after the preclean step 170, a salicide layer 180 is formed on the gate structures 120 and 130, the S/D regions 123 and 133, the N+-doped region 140 and the P+-doped region 150. The salicide layer may be a nickel salicide layer that is possibly formed with the following step. A layer of nickel is first sputtered onto the substrate 100, and then an annealing step is performed, preferably at about 400-600° C., to react nickel with the surface silicon atoms of the substrate 100 and the gate structures 120 and 130 to form nickel silicide. The unreacted nickel is then removed using a mixture of sulfuric acid and hydrogen peroxide, for example.

Since the NMOS transistor 102 is subject to PAI 165, it will not suffer from a piping problem in the salicide process due to inhibition of grain growth of the metal silicide. Meanwhile, the PMOS transistor 104 and the diodes 106 and 108 are not implanted in the PAI step 165, so that their qualities will not be lowered.

It is noted that though the NMOS transistor 102 is subject to PAI but the PMOS transistor 140 is not in the above embodiment, various types of NMOS transistors are usually not all implanted and various types of PMOS transistors not all masked in the PAI process in a real fabricating process. Most of the various types of NMOS transistors are subject to PAI, but a minority of NMOS transistors not suffering from salicide piping or not requiring formation of salicide, such as, the NMOS transistors (pass transistors) of DRAM cells, is masked in the PAI process. On the contrary, most of the various types of PMOS transistors are masked in the PAI step, but a minority of PMOS transistors is subject to PAI for solving other problems caused by ordered crystal lattice. Similarly, other devices suffering from ordered crystal lattice can also be subject to the PAI, while those easily lowered in quality by PAI can be masked by the mask layer in the PAI step.

Moreover, though a nickel salicide process is mentioned in the embodiment of this invention, the selective PAI process and the salicide process of this invention may also be applied to the cases where the suicides of other metal elements are used. It is because the conventional non-selective PAI process has been applied to the salicide processes of quite a few metal elements in the prior art.

Furthermore, in spite that the above selective PAI process of this invention is conducted before a salicide process to inhibit growth of metal silicide grains in the above embodiment, it may also be inserted before any other process where S/D regions of NMOS transistors are preferably pre-amorphized for solving certain problems caused by ordered crystal lattice.

It will be apparent to those skilled in the art that various modifications and variations can be made to the structure of the present invention without departing from the scope or spirit of the invention. In view of the foregoing, it is intended that the present invention covers modifications and variations of this invention provided they fall within the scope of the following claims and their equivalents.

What is claimed is:

1. A self-aligned silicide (salicide) process, comprising:
providing a substrate with an NMOS transistor and a PMOS transistor thereon;
forming a mask layer over the substrate covering the PMOS transistor but exposing the NMOS transistor;
performing a pre-amorphization implantation (PAI) step to the substrate using the mask layer as a mask;
removing the mask layer; and
forming a salicide layer on the NMOS transistor and the PMOS transistor.

2. The salicide process of claim 1, wherein the salicide layer comprises nickel silicide.

3. The salicide process of claim 1, further comprising a preclean step before the salicide layer is formed.

4. The salicide process of claim 3, wherein the preclean step comprises utilizing HF to clean surfaces of the substrate.

5. The salicide process of claim 1, wherein the substrate further has a diode thereon including an N+-doped region exposed on the substrate; and
the mask layer also covers the diode.

6. The salicide process of claim 1, wherein the substrate further has a diode thereon including a P+-doped region exposed on the substrate; and
the mask layer also covers the diode.

7. The salicide process of claim 1, wherein the PAI step implants arsenic ions into the NMOS transistor.

8. The salicide process of claim 7, wherein an implantation energy of 15-25 keV is set in the PAI step.

9. A selective pre-amorphization implantation (PAI) process, comprising:
providing a substrate with an NMOS transistor and a PMOS transistor thereon;
forming a mask layer over the substrate covering the PMOS transistor but exposing the NMOS transistor; and
performing an amorphization implantation step to the substrate using the mask layer as a mask.

10. The selective PAI process of claim 9, wherein the substrate further has a diode thereon including an N+-doped region exposed on the substrate; and
the mask layer also covers the diode.

11. The selective PAI process of claim 9, wherein the substrate further has a diode thereon including a P+-doped region exposed on the substrate; and
the mask layer also covers the diode.

12. The selective PAI process of claim 9, wherein the amorphization implantation step implants arsenic ions into the NMOS transistor.

13. The selective PAI process of claim 12, wherein an implantation energy of 15-25 keV is set in the amorphization implantation step.
